(19) United States
(12) Patent Application Publication
(10) Pub. No.: US 2024/0213040 A1
(43) Pub. Date: Jun. 27, 2024

(54) SYSTEMS AND APPARATUS FOR SEMICONDUCTOR EQUIPMENT

(71) Applicant: ASM IP Holding B.V., Almere (NL)

(72) Inventor: Mun Peow Wong, Phoenix, AZ (US)

(21) Appl. No.: 18/391,815

(22) Filed: Dec. 21, 2023

Related U.S. Application Data
(60) Provisional application No. 63/435,376, filed on Dec. 27, 2022.

(51) Int. Cl. H01L 21/67

(52) U.S. Cl. CPC H01L 21/67017; H01L 21/67196

(57) ABSTRACT

Various embodiments of the present technology may provide an apparatus for removing oxygen and moisture from a semiconductor system. The apparatus may be coupled to a wafer handling chamber and include a blower, a first air purifier, a second air purifier, and a particle filter. The first and second air purifiers may be coupled in parallel to each other and downstream from the blower. The particle filter may be coupled downstream from the first and second air purifiers. The wafer handling chamber may include a fan integrated within a lower region of the wafer handling chamber.

### CROSS-REFERENCE TO RELATED APPLICATIONS

This application is a nonprovisional of, and claims priority to and the benefit of, U.S. Provisional Patent Application No. 63/435,376, filed Dec. 27, 2022 and entitled “SYSTEMS AND APPARATUS FOR SEMICONDUCTOR EQUIPMENT,” which is hereby incorporated by reference herein.

### FIELD OF INVENTION

The present disclosure generally relates to a system for semiconductor equipment. More particularly, the present disclosure relates to a system for removing moisture and oxygen in the system.

### BACKGROUND OF THE TECHNOLOGY

Semiconductor manufacturing tools typically include a wafer handling chamber that is used to hold a wafer when the wafer is being transferred from one reaction chamber to another. In conventional systems, the wafer handling chamber is held at a high vacuum condition to remove moisture and oxygen from the wafer handling chamber. However, during the wafer transfer process, the wafer handling chamber must be at a low vacuum condition. The time required to provide a high vacuum condition and then a low vacuum condition for each wafer transfer decreases wafer throughput.

### SUMMARY OF THE INVENTION

Various embodiments of the present technology may provide an apparatus for removing oxygen and moisture from a semiconductor system. The apparatus may be coupled to a wafer handling chamber and include a blower, a first air purifier, a second air purifier, and a particle filter. The first and second air purifiers may be coupled in parallel to each other and downstream from the blower. The particle filter may be coupled downstream from the first and second air purifiers. The wafer handling chamber may include a fan integrated within a lower region of the wafer handling chamber.

According to one aspect, an apparatus comprises: a wafer handling chamber comprising: an upper region comprising a plurality of openings; and a lower region, positioned below the upper region, comprising a fan; and an air handling system coupled to the wafer handling chamber and configured to circulate air, the air handling system comprising: a blower downstream from the fan; a set of purifiers comprising: a first purifier downstream from the blower; and a second purifier downstream from the blower and coupled to the first purifier; and a particle filter downstream from the set of purifiers and coupled between the set of purifiers and the fan.

In an embodiment of the above apparatus, each of the first and second purifiers are configured to remove oxygen and water from the air.

In an embodiment of the above apparatus, the second purifier is coupled in parallel with the first purifier.

In an embodiment of the above apparatus, the apparatus further comprises a first valve disposed between the set of purifiers and the blower and configured to control a direction of air flow through the set of purifiers.

In an embodiment of the above apparatus, the air handling system further comprises: a second valve disposed at an outlet of the first purifier; and a third valve disposed at an outlet of the second purifier.

In an embodiment of the above apparatus, the fan comprises a fan cowling that is integrated into a sidewall of the wafer handling chamber.

In an embodiment of the above apparatus, the fan comprises a centrifugal fan configured to draw air from the upper region of the wafer handling chamber and push it to the air handling system.

In an embodiment of the above apparatus, each of the first and second purifiers comprises a plurality of porous pellets configured to absorb moisture from the air.

In an embodiment of the above apparatus, each of the first and second purifiers comprises a catalyst configured to absorb oxygen from the air.

In an embodiment of the above apparatus, the wafer handling chamber further comprises a mechanically-driven arm configured to pass through each opening.

In yet another aspect, an apparatus comprises: a wafer handling chamber comprising: an upper region comprising a plurality of openings; and a lower region, positioned below the upper region, comprising an air outlet and an air inlet; and an air handling system coupled to the wafer handling chamber and configured to circulate air, the air handling system comprising: a blower comprising: an inlet coupled to the air outlet and configured to pull air from the wafer handling chamber; and an outlet configured to expel air; a set of purifiers coupled to the outlet of the blower and configured to remove oxygen and water from the air; and a particle filter downstream from the set of purifiers and coupled to the air inlet of the wafer handling chamber.

In an embodiment of the above apparatus, the set of purifiers comprises: a first purifier coupled to the outlet of the blower; and a second purifier coupled to the outlet of the blower and coupled in parallel with the first purifier.

In an embodiment of the above apparatus, each of the first and second purifiers comprises: a plurality of porous pellets configured to absorb moisture from the air; and a catalyst configured to absorb oxygen from the air.

In an embodiment of the above apparatus, the apparatus further comprises a valve disposed between the set of purifiers and the blower and configured to control a direction of air flow through the set of purifiers.

In an embodiment of the above apparatus, the wafer handling chamber further comprises a mechanically-driven arm configured to pass through each opening.

In an embodiment of the above apparatus, the wafer handling chamber further comprises a fan disposed in the bottom portion, and wherein the fan comprises a centrifugal fan configured to draw air from the upper region of the wafer handling chamber and push it to the air handling system.

In yet another aspect, a system comprises: a wafer handling chamber comprising: an upper region comprising a plurality of openings; and a lower region, positioned below the upper region, comprising an air outlet and an air inlet; a plurality of reaction chambers, wherein each reaction chamber is coupled to a respective opening from the plurality of openings; and an air handling system coupled to the wafer handling chamber and configured to circulate air, the air handling system comprising: a blower comprising: an inlet coupled to the air outlet and configured to pull air from the wafer handling chamber; and an outlet configured to expel air; a set of purifiers coupled to the outlet of the blower and configured to remove oxygen and water from the air; and a particle filter downstream from the set of purifiers and coupled to the air inlet of the wafer handling chamber.

In an embodiment of the above system, the set of purifiers comprises: a first purifier coupled to the outlet of the blower; and a second purifier coupled to the outlet of the blower and coupled in parallel with the first purifier.

In an embodiment of the above system, the system further comprises: a first valve disposed between the set of purifiers and the blower and configured to control a direction of air flow through the set of purifiers; a second valve disposed at an outlet of the first purifier; and a third valve disposed at an outlet of the second purifier.

In an embodiment of the above system, the wafer handling chamber further comprises a fan disposed in the bottom portion, and wherein the fan comprises a centrifugal fan configured to draw air from the top portion of the wafer handling chamber and push it to the air handling system.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a top view of a system in accordance with an exemplary embodiment of the present technology;

FIG. 2 is a block diagram of a portion of the system in accordance with an exemplary embodiment of the present technology;

FIG. 3 illustrates a wafer handling chamber in accordance with an embodiment of the present technology;

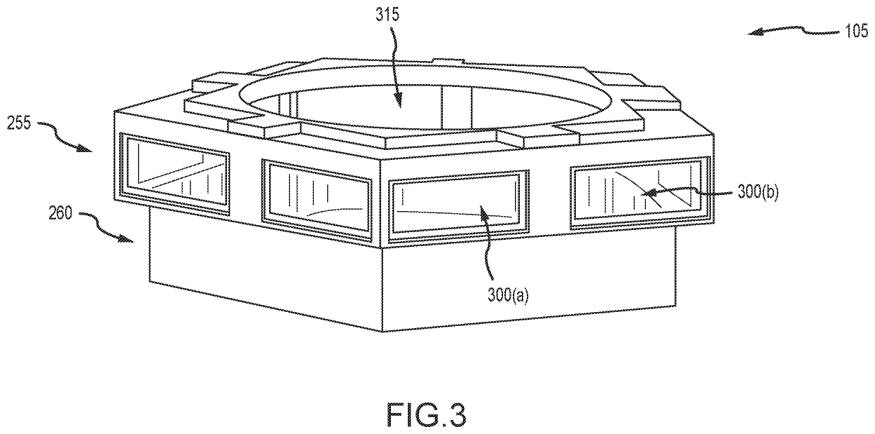

FIG. 4 representatively illustrates a cross-sectional view of the wafer handling chamber in accordance with an embodiment of the present technology; and

FIG. 5 representatively illustrates a portion of the system in accordance with an exemplary embodiment of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various reaction chambers, fans, purifiers, and pumps. Further, the present technology may have any number of tool layouts.

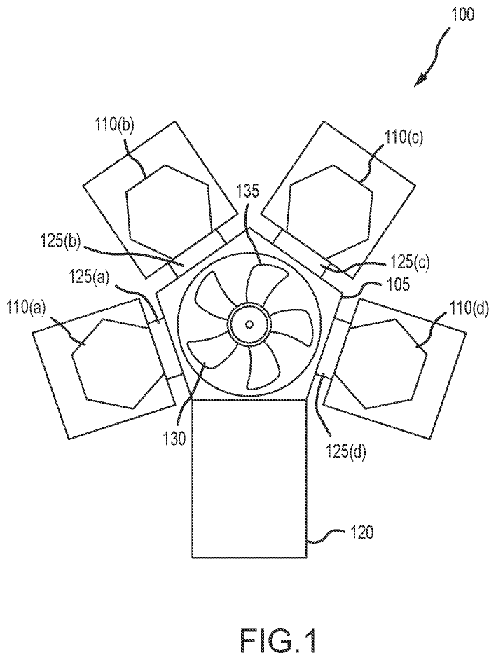

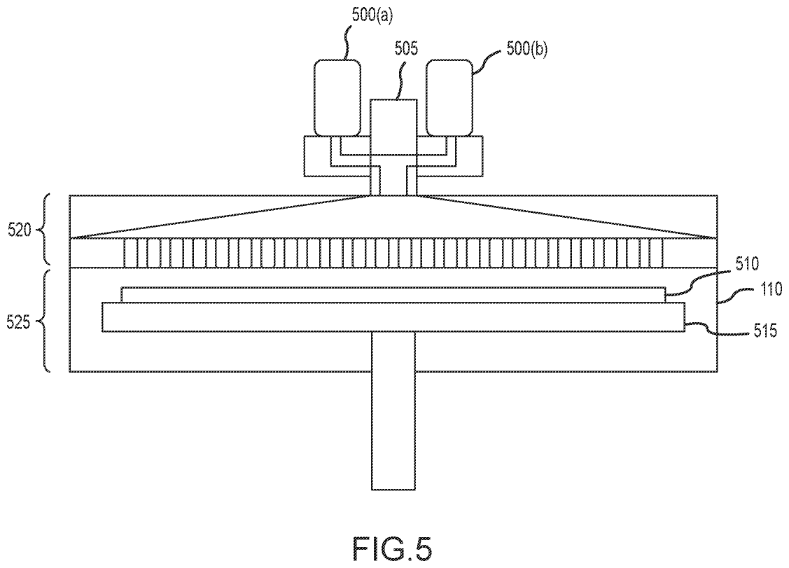

Referring to FIGS. 1 and 5, an exemplary system 100 may comprise a wafer handling chamber 105, a reactor 110 for processing a substrate, such as a wafer (510), and an air handling system 115. In various embodiments, the system 100 may further comprise a front end module 120. In various embodiments, the system 100 may comprise a plurality of reactors, such as a first reactor 110(a), a second reactor 110(b), a third reactor 110(c), and a fourth reactor 110(d).

In various embodiments, the front end module 120 stores the wafer prior to processing. In some embodiments, a robot (not shown), disposed within the wafer handling chamber 105, may be used to transfer the wafer from the front end module 120 to the wafer handling chamber 105. In various embodiments, the robot may also be used to transfer a wafer from one reactor, such as the first reactor 110(a), to a different reactor, such as the second reactor 110(b).

In various embodiments, the reactor 110 may be configured for processing a substrate, such as the wafer 510. For example, the reactor 110 may comprise a reaction chamber 525 to receive the wafer 510 for processing and gas distribution system 520. The gas distribution system 520 may be configured to deliver a precursor or reactant to the reaction chamber 525. The reactor 110 may further comprise a susceptor 515 to support the substrate during processing. In various embodiments, the susceptor 515 may comprise heating elements (not shown) and/or cooling elements (not shown). In various embodiments, the susceptor 515 may comprise electrodes (not shown) capable of providing an electrostatic chucking function. In some embodiments, the gas distribution system 525 may be positioned above the reaction chamber 525 and susceptor 515. However, in other embodiments, the gas distribution system 520 may be positioned lateral to the susceptor 515. Each reactor 110 from the plurality of reactors may be configured to provide desired processing parameters, such as pressure and temperature, to achieve a desired process result.

In various embodiments, the system 100 may further comprise a valve manifold 505 coupled to the gas distribution system 520 and configured to deliver a precursor or reactant to the reaction chamber 525 via the gas distribution system 520. Accordingly, the valve manifold 505 may be coupled to one or more source vessels used to contain the precursor or reactant. For example, the valve manifold 505 may comprise any number of ports (not shown). Each port may be connected to a source vessel via an interconnect line.

According to an exemplary embodiment, the system 100 may comprise a cartridge 500, for example a first cartridge 500(a) and a second cartridge 500(b). In an exemplary embodiment, the cartridge 500 may be configured to attach directly to a port of the valve manifold 505 without the use of interconnect lines. In various embodiments, the cartridge 500 may be configured to hold just enough chemistry for a single process, such as a chamber coating process that is performed prior to deposition cycles. For example, each cartridge 500(a), 500(b) may have a volume in a range of 4 cc to 15 cc. In an exemplary embodiment, the first cartridge 500(a) may have a volume in the range of 4 cc to 6 cc of water, and the second cartridge 500(b) may have a volume in the range of 10 cc to 12 cc and contain trimethylamine. In particular, to achieve a chamber coating process with 2500 cycles, 11.3 cc of trimethylamine and 4.7 cc of water may be used. Accordingly, the first and second cartridges 500(a), 500(b) may be sized to have a volume that is the same or a slightly greater than the amount of substance/chemistry needed for a particular process.

In various embodiments, the system 100 may further comprise a valve system 125 to create a seal and barrier between the wafer handling chamber 105 and the reactor 110 to preserve the environment (e.g., temperature and pressure parameters) of the wafer handling chamber 105 as well as the reactor 110. The valve system 125 may comprise a mechanism that opens and closes to create an opening, as well as a sealing component.

The valve system 125 may be configured to allow a wafer to pass through the opening of the mechanism. Accordingly, the opening of the mechanism is sized to allow passage of a wafer. In an exemplary embodiment, the system 100 may comprise a plurality of valve systems, such as a first valve system 125(a) disposed between the wafer handling chamber 105 and the first reactor 110(a), a second valve system 125(b) disposed between the wafer handling chamber 105 and the second reactor 110(b), a third valve system 125(c) disposed between the wafer handling chamber 105 and the third reactor 110(c), a fourth valve system 125(d) disposed between the wafer handling chamber 105 and the fourth reactor 110(d). The valve system 125 may be responsive to a control module (not shown) that controls the opening and closing of the valve system 120. In an exemplary embodiment, each valve system 125 may operate independently from the other valve systems.

In various embodiments, the wafer handling chamber 105 may provide a controlled environment to prevent contamination of a wafer and/or prevent outside air from entering an interior space of the wafer handling chamber 105. For example, the wafer handling chamber 105 may be sealed off from the front end module 120 and/or the reactor 110 by the respective valve system 125. In addition, the wafer handling chamber 110 may be configured to allow a wafer to be transferred from one reactor to a different reactor via the valve system 125.

In various embodiments, the wafer handling chamber 105 may comprise an upper region 255 and a lower region 260 that is disposed below the upper region 255. The upper region 255 may comprise a first sidewall 305, and the lower region 260 may comprise a second sidewall 310. The first sidewall 305 may be coupled to the second sidewall 310, and the first sidewall together with the second sidewall 310 may define an interior region 315 of the wafer handling chamber 105.

In various embodiments, the upper region 255 may further comprise an opening 300 within the first sidewall. In an exemplary embodiment, the upper region 255 comprises a plurality of openings, wherein each opening couples to a respective valve system 125 and a respective reactor 110. For example, a first opening 300(a) may be coupled to the first valve system 125 and the first reactor 110(a). Similarly, a second opening 300(b) may be coupled to the second valve system 125(b) and the second reactor 110(b).

In various embodiments, the wafer handling chamber 105 may further comprise a fan 130 disposed in the lower region 260. Accordingly, the fan 130 may be positioned below the opening 300. In various embodiments, the fan 130 may be configured to draw air from the upper region 255 and push it to the air handling system 200. The fan 130 may be arranged horizontally within the lower region 260, such that a center point of the fan 130 is aligned with a geometric center of the wafer handling chamber 105 when viewed from the top. In an exemplary embodiment, the fan 130 may comprise a centrifugal fan. In addition, in various embodiments, the fan 130 may be integrated into the second sidewall 310. In particular, the second sidewall 310 may function as a fan cowling of the fan 130.

In various embodiments, the wafer handling chamber 105 may comprise an outlet disposed adjacent to the fan 130. For example, the outlet may be disposed in the lower region 260 of the wafer handling chamber 105 such that air from the upper region 255 can be pushed, by the fan 130, out of the outlet of the wafer handling chamber 105. In addition, the wafer handling chamber 105 may comprise an inlet disposed above the fan 130, for example in or near the upper region 255 of the wafer handling chamber 105.

In various embodiments, the air handling system 200 be configured to circulate, purify, and remove particles from the air in the wafer handling chamber 105. In various embodiments, the air handling chamber 200 may comprise a blower 205, a first purifier 210, a second purifier 215, and a filter 220. In various embodiments, the air handling system 200 may comprise an inlet 240 and an outlet 245. The inlet 240 of the air handling system 200 may be coupled to the outlet of the wafer handling chamber 105. Similarly, the outlet 245 of the air handling system 200 may be coupled to the inlet of the of the wafer handling chamber 105.

In various embodiments, the blower 205 may be configured to push air, from the wafer handling chamber 105, through at least one of the first and second purifiers 210, 215. In an exemplary embodiment, the blower 205 may comprise a fan (not shown) and a motor (not shown). However, the blower 205 may comprise any suitable blower device or system.

In various embodiments, the first and second purifiers 210, 215 may be configured to remove oxygen and moisture (e.g., water) from the air. For example, each purifier 210, 215 may comprise a plurality of porous pellets (not shown) configured to absorb moisture from the air. In addition, each of the first and second purifiers 210, 215 may comprise a material configured to absorb oxygen from the air. The material may comprise a catalyst (e.g., a copper catalyst), a crystalline material that can bind and store oxygen, or a chemical that absorbs oxygen.

In an exemplary embodiment, the first and second purifiers 210, 215 are coupled to an outlet of the blower 205. In other words, the first and second purifiers 210, 215 may be downstream from the blower 205. In addition, in an exemplary embodiment, the first and second purifiers 210, 215 are coupled in parallel with each other. In other words, inlets of the purifiers 210, 215 are connected to each other and outlets of the purifiers 210, 215 are connected to each other.

In an exemplary embodiment, the air handling system 200 may further comprise a filer 220 configured to remove particles from the air circulating through the air handling system 200. In particular, the filter 220 remove or otherwise trap particles from the air flowing out of either one of the purifiers 210, 215. The filter 220 may comprise any suitable filter to remove particles of a particular size and/or type.

In various embodiments, the air handling system 200 may further comprise a plurality of valves, such as a first valve 225, a second valve 230, and a third valve 235. Each valve 225, 230, 235 may be responsive to a respective valve control signal generated and transmitted from the control module (not shown). In an exemplary embodiment, each valve 225, 230, 235 may be operated independently from each other.

In an exemplary embodiment, the first valve 225 be configured to control a direction of air flow. The first valve 225 may comprise a single inlet coupled to an outlet of the blower 205. The first valve 225 may further comprise a first outlet and a second outlet, wherein the first outlet is coupled to an inlet of the first purifier 210 and the second outlet is coupled to the inlet of the second purifier 215. For example, the first valve 225 may allow air to flow from the blower 205 to the first purifier 210 while blocking air flow to the second purifier 215. Similarly, the first valve 225 may allow air to flow from the blower 205 to the second purifier 215 while blocking air flow to the first purifier 210. In various embodiments, the first valve 225 may comprise a three-way valve, a switching valve, or the like. In addition, the first valve 225 may comprise a pneumatic valve, a hydraulic valve, or the like.

In an exemplary embodiment, the second valve 230 be configured to control a direction of air flow. The second valve 230 may comprise a single inlet coupled to an outlet of the first purifier 210 and a single outlet coupled to the inlet of the filter 220. For example, the second valve 230 may allow air to flow from the first purifier 210 to the filter 220. The second valve 230 may be configured to allow air to flow in one direction. For example, the second valve 230 may prevent air from flowing from the second purifier 215 to the first purifier 210. In various embodiments, the second valve 230 may comprise a single-direction valve. In addition, the second valve 230 may comprise a pneumatic valve, a hydraulic valve, or the like.

In an exemplary embodiment, the third valve 235 be configured to control a direction of air flow. The third valve 235 may comprise a single inlet coupled to an outlet of the second purifier 215 and a single outlet coupled to the inlet of the filter 220. The outlet of the third valve 235 may also be coupled to the outlet of the second valve 230. For example, the third valve 235 may allow air to flow from the second purifier 215 to the filter 220. The third valve 235 may be configured to allow air to flow in one direction. For example, the third valve 235 may prevent air from flowing from the outlet of the first purifier 210 to the outlet of the second purifier 215. In various embodiments, the third valve 235 may comprise a single-direction valve. In addition, the third valve 235 may comprise a pneumatic valve, a hydraulic valve, or the like.

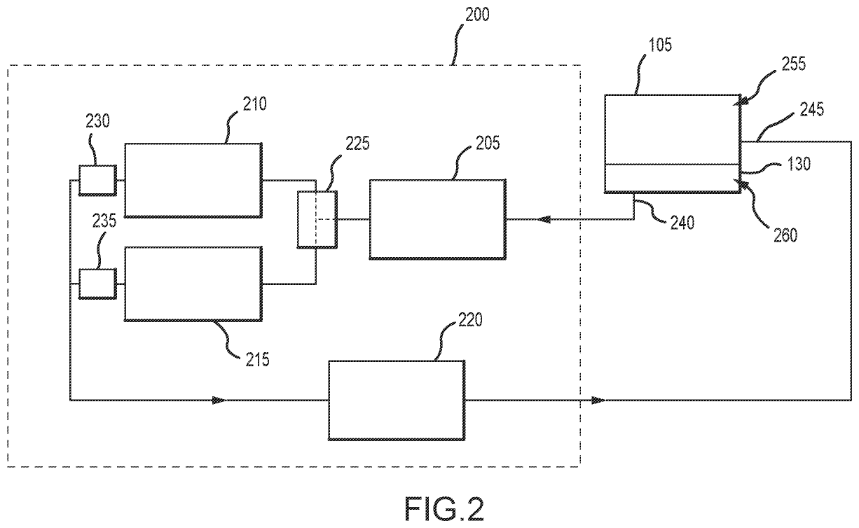

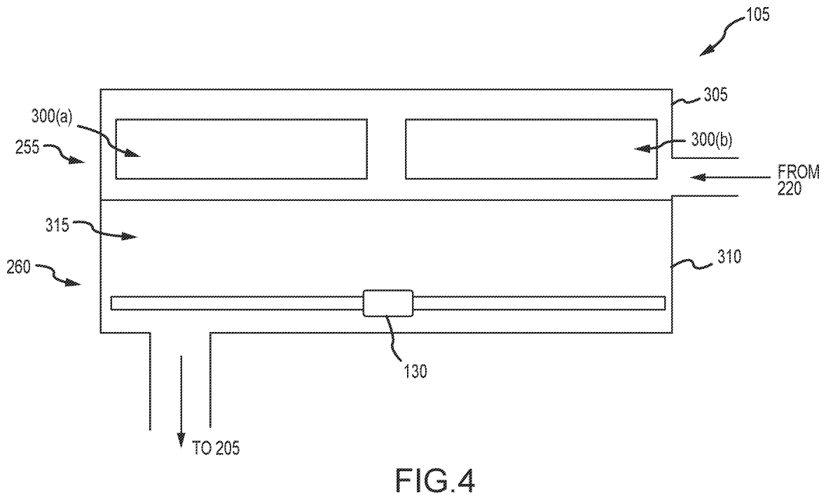

In operation, and referring to FIGS. 2 and 4, air from the wafer handling chamber 105 may be recirculated through the air handling system 200 and passed back into the wafer handling chamber 105. For example, the fan 130 may push air from the wafer handling chamber 105 to the blower 205. The blower 205 may then blow the air through the first valve 225 and into one of the first or second purifiers 210, 215. For example, the first valve 225 may be selectively operated to divert the air to the first purifier 210 or the second purifier 215.

In an exemplary embodiment, only one air purifier is being utilized at any given time. For example, if the first air purifier 210 is being utilized, the second valve 230 is open to allow the air to pass to the filter 220. In addition, the third valve 235 is closed to prevent air from flowing back into the second purifier 215.

Alternatively, if the second purifier 215 is being utilized, the third valve 235 is open to allow air to pass to the filter 220. In addition, the second valve 230 is closed to prevent air from flowing back into the first purifier 210.

In an exemplary embodiment, after the air passes through the filter 220, it is directed back into the wafer handling chamber 105. In particular, the air is directed to the upper region 255 of the wafer handling chamber 150.

In various embodiments, the air handling system 105 may provide air recirculation continuously.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system. The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a wafer handling chamber comprising:
an upper region comprising a plurality of openings; and
a lower region, positioned below the upper region, comprising a fan; and
an air handling system coupled to the wafer handling chamber and configured to circulate air, the air handling system comprising:
a blower downstream from the fan;
a set of purifiers comprising:
a first purifier downstream from the blower; and
a second purifier downstream from the blower and coupled to the first purifier; and
a particle filter downstream from the set of purifiers and coupled between the set of purifiers and the fan.

2. The apparatus according to claim 1, wherein each of the first and second purifiers are configured to remove oxygen and water from the air.

3. The apparatus according to claim 1, wherein the second purifier is coupled in parallel with the first purifier.

4. The apparatus according to claim 1, further comprising a first valve disposed between the set of purifiers and the blower and configured to control a direction of air flow through the set of purifiers.

5. The apparatus according to claim 1, wherein the air handling system further comprises:
a second valve disposed at an outlet of the first purifier; and
a third valve disposed at an outlet of the second purifier.

6. The apparatus according to claim 1, wherein the fan comprises a fan cowling that is integrated into a sidewall of the wafer handling chamber.

7. The apparatus according to claim 1, wherein the fan comprises a centrifugal fan configured to draw air from the upper region of the wafer handling chamber and push it to the air handling system.

8. The apparatus according to claim 1, wherein each of the first and second purifiers comprises a plurality of porous pellets configured to absorb moisture from the air.

9. The apparatus according to claim 1, wherein each of the first and second purifiers comprises a catalyst configured to absorb oxygen from the air.

10. The apparatus according to claim 1, wherein the wafer handling chamber further comprises a mechanically-driven arm configured to pass through each opening.

11. An apparatus, comprising:
a wafer handling chamber comprising:
an upper region comprising a plurality of openings; and
a lower region, positioned below the upper region, comprising an air outlet and an air inlet; and
an air handling system coupled to the wafer handling chamber and configured to circulate air, the air handling system comprising:
a blower comprising:
an inlet coupled to the air outlet and configured to pull air from the wafer handling chamber; and
an outlet configured to expel air;
a set of purifiers coupled to the outlet of the blower and configured to remove oxygen and water from the air; and
a particle filter downstream from the set of purifiers and coupled to the air inlet of the wafer handling chamber.

12. The apparatus according to claim 11, wherein the set of purifiers comprises:
a first purifier coupled to the outlet of the blower; and
a second purifier coupled to the outlet of the blower and coupled in parallel with the first purifier.

13. The apparatus according to claim 12, wherein each of the first and second purifiers comprises:
a plurality of porous pellets configured to absorb moisture from the air; and
a catalyst configured to absorb oxygen from the air.

14. The apparatus according to claim 12, further comprising a valve disposed between the set of purifiers and the blower and configured to control a direction of air flow through the set of purifiers.

15. The apparatus according to claim 11, wherein the wafer handling chamber further comprises a mechanically-driven arm configured to pass through each opening.

16. The apparatus according to claim 11, wherein the wafer handling chamber further comprises a fan disposed in the bottom portion, and wherein the fan comprises a centrifugal fan configured to draw air from the upper region of the wafer handling chamber and push it to the air handling system.

17. A system, comprising:
a wafer handling chamber comprising:
an upper region comprising a plurality of openings; and
a lower region, positioned below the upper region, comprising an air outlet and an air inlet;
a plurality of reaction chambers, wherein each reaction chamber is coupled to a respective opening from the plurality of openings; and
an air handling system coupled to the wafer handling chamber and configured to circulate air, the air handling system comprising:
a blower comprising:
an inlet coupled to the air outlet and configured to pull air from the wafer handling chamber; and
an outlet configured to expel air;
a set of purifiers coupled to the outlet of the blower and configured to remove oxygen and water from the air; and
a particle filter downstream from the set of purifiers and coupled to the air inlet of the wafer handling chamber.

18. The system according to claim 17, wherein the set of purifiers comprises:
a first purifier coupled to the outlet of the blower; and
a second purifier coupled to the outlet of the blower and coupled in parallel with the first purifier.

19. The system according to claim 18, further comprising:
a first valve disposed between the set of purifiers and the blower and configured to control a direction of air flow through the set of purifiers;
a second valve disposed at an outlet of the first purifier; and
a third valve disposed at an outlet of the second purifier.

20. The system according to claim 17, wherein the wafer handling chamber further comprises a fan disposed in the bottom portion, and wherein the fan comprises a centrifugal fan configured to draw air from the top portion of the wafer handling chamber and push it to the air handling system.
